(19) United States
(12) Patent Application Publication
(10) Pub. No.: US 2007/0076376 A1
(43) Pub. Date: Apr. 5, 2007

(54) Method, apparatus and computer system for providing for the transfer of thermal energy

(75) Inventors: Rajiv K. Mongia, Portland, OR (US); Himanshu Pokharna, San Jose, CA (US); Eric DiStefano, Livermore, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: INTEL CORPORATION

(21) Appl. No.: 11/239,987

(22) Filed: Sep. 30, 2005

(51) Int. Cl. H05K 7/20

(52) U.S. Cl. 361/700

(57) ABSTRACT

A method, apparatus and computer system are described for providing for the transfer of heat from electronic components. The computer system includes a frame and an apparatus. The apparatus includes a chassis component with a heat pipe, a heat exchanger, a conduit of tubing, a cold plate, and a pump to provide for the flow of the fluid between the heat exchanger and the cold plate. The heat pipe is thermally coupled between the cold plate and the heat exchanger to provide for the transfer of thermal energy from the cold plate to the heat exchanger independently of the conduit of tubing. The heat pipe may transfer a substantial amount of the thermal energy from the cold plate to the heat exchanger. The heat pipe may operate passively and provide cooling in an ambient manner.

### BACKGROUND

1. Technical Field

One or more embodiments of the present invention generally relate to cooling systems. More specifically, the embodiments relate to an apparatus, computer system and method for providing for the transfer of heat, wherein a heat pipe is provided to lower the temperature of a electronic components or surfaces of electronic components in conjunction with a pumped loop.

2. Discussion

In recent years, electronic components and systems have been made to operate at faster speeds. Developments in electronic components, such as processors or cores with one or more processors for computing systems, have been made to meet increasing demands for better performance and reduced size. Thus, these demands have led to a decrease in the weight and an increase in the density of components. These factors lead to increases in heat generation. Particularly in mobile computing environments, these factors can lead to overheating, which may negatively affect performance, and can significantly reduce battery life.

The above-mentioned factors increase the need for effective cooling for electronic systems. Two types of cooling are generally implemented: air and liquid. In liquid cooling, a heat exchanger may be implemented to remove heat from the liquid, which indirectly removes heat from the electronic components. Pumped loops have been proposed for achieving higher heat dissipation rates at a hot spot, such as an electronic component. FIG. 1 illustrates a conventional pumped loop configuration.

In FIG. 1, a liquid cooling system of prior art design shows a chassis component 101 residing within a computer system 100. The chassis component includes a cold plate 102 thermally coupled to an electronic component 104. Tubing 106 provides for the flow of a liquid from the cold plate 102 to a heat exchanger 110. The heat exchanger 110 serves to radiate heat from the liquid flowing through the tubing 106 to a frame component 112. A pump 108, powered by a battery or other power supply, pushes the liquid through the tubing 106.

A computer system 100 with chassis component 101 is provided with an increased cooling capacity. This allows for increases in the thermal design power (TDP) of the computer system, specifically at the electronic component 104. The computer system 100, therefore, may be afforded an increase in overall power requirements as the pump 108 requires power, and the electronic component 104 is able to operate at higher levels of performance and power. As previously mentioned, increases in power requirements, particularly in mobile environments, may negatively affect the performance of the computer system.

Therefore, there is a need for alternative cooling systems for computer systems, such as computer system 100. In particular, there is a need for cooling systems that, at least, do not significantly increase the average power requirements.

### BRIEF DESCRIPTION OF THE DRAWINGS

Various advantages of embodiments of the present invention will become apparent to one of ordinary skill in the art by reading the following specification and appended claims, and by referencing the following drawings, in which:

FIG. 1 is an illustrative example of a prior art design of a liquid cooling system;

FIG. 2 is an illustrative example of a liquid cooling system according to one embodiment of the invention;

FIG. 3 is a cross-sectional diagram of a cold plate with a heat pipe according to one embodiment of the invention;

FIG. 4 is a cross-sectional diagram of a manifold plate with a heat pipe according to one embodiment of the invention;

FIGS. 5-8 are cross-sectional diagrams of various examples of heat pipe shapes according to embodiments of the invention;

FIG. 9 illustrates examples of heat pipe configurations according to embodiments of the invention; and

FIG. 10 shows a flow diagram of the transfer of thermal energy by a heat pipe in a computer system according to an embodiment of the invention.

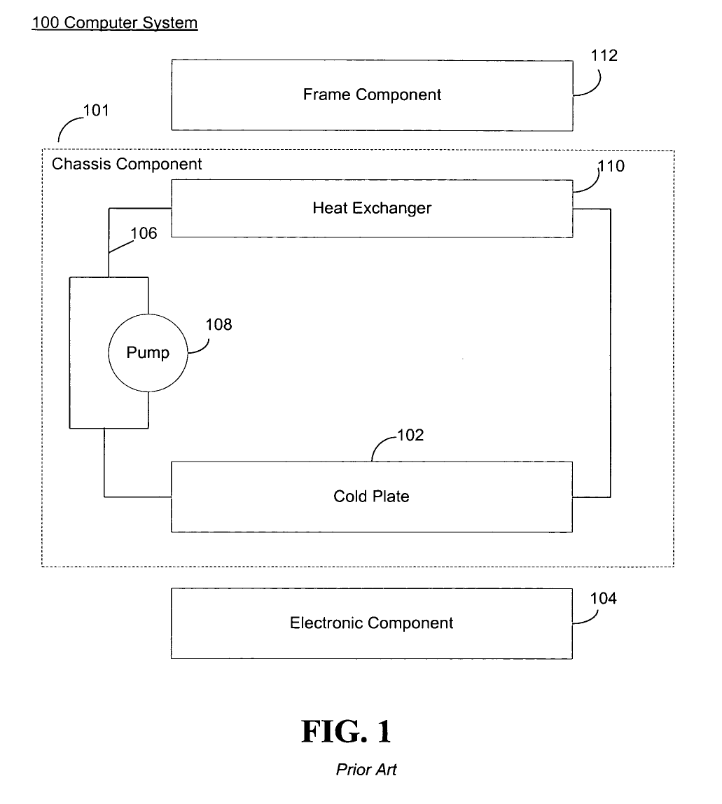

### DETAILED DESCRIPTION

Reference is made to embodiments of the invention, examples of which are illustrated in the accompanying drawings. While the present invention will be described in conjunction with the embodiments, it will be understood that they are not intended to limit the invention to these embodiments. On the contrary, the invention is intended to cover alternatives, modifications and equivalents, which may be included within the spirit and scope of the invention as defined by the appended claims. Moreover, in the following detailed description of the invention, numerous specific details are set forth in order to provide a thorough understanding of the invention. However, the invention may be practiced without these specific details. In other instances, well-known methods, procedures, components and circuits have not been described in detail as not to unnecessarily obscure aspects of the invention.

Embodiments of the invention are directed to a method, apparatus and computer system for providing for the transfer of heat from electronic components. Embodiments of the computer system may include a frame and an apparatus. In embodiments of the invention, the apparatus may include a chassis component with a heat pipe, a heat exchanger, a conduit of tubing, a cold plate, and a pump to provide for the flow of the fluid between the heat exchanger and the cold plate. The heat pipe may be thermally coupled between the cold plate and the heat exchanger to provide for the transfer of thermal energy from the cold plate to the heat exchanger independently of the conduit of tubing. The heat pipe may transfer a substantial amount of the thermal energy from the cold plate to the heat exchanger. The heat pipe may operate in an ambient manner. In one embodiment of the invention, the heat exchanger, conduit of tubing, pump, and cold plate form a pumped loop.

According to one embodiment, the heat pipe may thermally couple the cold plate to the heat exchanger. According to embodiments of the invention, the heat exchanger comprises a thermally conductive tube, which may be molded into a series of thermally conductive fins and integral mounting features. The conduit of tubing may, for example, be thermally conductive metal tube. However, other type of suitable material that allows the fluids, such as, but not limited to, hot liquid, air or cooling agent to flow through may also be used.

Reference in the specification to “one embodiment” or “an embodiment” of the invention means that a particular feature, structure or characteristic described in connection with the embodiment is included in at least one embodiment of the invention. Thus, the appearances of the phrase “in one embodiment” or “according to an embodiment” appearing in various places throughout the specification are not necessarily all referring to the same embodiment.

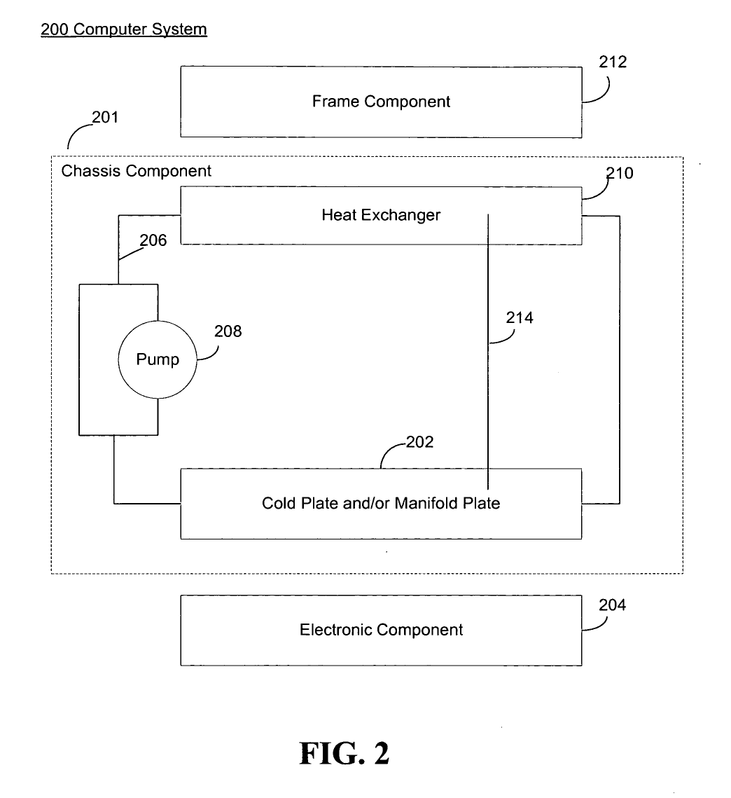

FIG. 2 is an illustrative example of a liquid cooling system according to one embodiment of the invention. In FIG. 2, a liquid cooling system according to one embodiment of the invention includes a chassis component 201 residing within a computer system 200. The chassis component 201 includes a cold plate 202 thermally coupled to an electronic component 204. Tubing 206 provides for the flow of a liquid from the cold plate or manifold 202 to a heat exchanger 210. The heat exchanger 210 serves to transfer heat from the liquid flowing through the tubing 206 to a frame component 212. In one embodiment, the frame component 212 may include one or more fans (not shown); and the fan(s) may be exposed to ambient air. One of ordinary skill in the relevant art would appreciate how to implement the use of the fan in the frame component 212, based at least on the teachings provided herein. A pump 208, powered by a battery or other power supply, pushes the liquid through the tubing 206.

In embodiments of the invention, the tubing 206, as well as the heat pipe 214, may be flexible or rigid. It is noted that even a somewhat (or less than completely) flexible tubing may be preferably used to connect cold plate and/or manifold plate 202 and the pump 208 to the heat exchanger 210 because a flexible tubing may be easily routed around other components inside a system in which embodiments of the chassis component 201 of the invention may operate and accommodate a greater number of chassis designs.

According to one embodiment of the invention, a heat pipe 214 is included and may provide for a substantial amount of the thermal energy generated by the electronic component 204 to be transferred to the heat exchanger 212. Furthermore, in one embodiment of the invention, the cold plate or a cold plate that includes a manifold plate (element 202) may be replaced with other types of heat sink(s). According to embodiments of the invention, element 202 may be a thermally conductive block on which the electronic component 204 may either directly mount or may be closely positioned for heat removal. In one embodiment, the thermally conductive block may be in the shape of a plate with one or more groove(s), a channel(s) or a thermally conductive tube(s) running through it.

In one embodiment of the invention, the heat pipe may include one or more of the following: an evaporator block with an evaporator block internal volume that may provide for the transfer of the thermal energy from the cold plate or a manifold plate which is included in the cold plate (element 202); a capillary wicking material in the evaporator block internal volume; and a heat pipe fluid flowing into the evaporator block internal volume, the capillary wicking material that may provide for the transport of the thermal energy during evaporation of the heat pipe fluid at the evaporator block, as well as the condensation of the heat pipe fluid at a condenser end in the heat exchanger 210, the evaporator block internal volume that may provide for the evaporation of the heat pipe fluid as a result of the thermal energy, and the heat exchanger 210 that may provide for the transfer of thermal energy from the heat pipe fluid to the heat exchanger 210, which may, according to embodiments of the invention, eventually lead to the transfer of the thermal energy to ambient air. According to embodiments of the invention, the fluid in the conduit tubing may be a liquid coolant, such as a distilled water, ethylene/propylene, or glycol mixture. Other types of liquid coolant, such as water or water with mixture of ions, may also be used, as long as they serve the function of cooling, as one of ordinary skill in the relevant art would appreciate based at least on the teachings provided herein.

Alternative types of heat pipes may be employed by the embodiments of the invention, and the above description is not intended to limit the scope of the embodiments. One of ordinary skill in the art would appreciate that other types of heat pipes may be used, in accordance with the embodiments of the invention, based at least on the teachings provided herein.

When heat is generated by the electronic component 204, according to one embodiment of the invention, the heat may be transferred from the electronic component 204 to the cold plate and/or manifold plate 202. In one embodiment of the invention, the electronic component may be directly attached to the surface of the cold plate and/or manifold plate 202. Preferably, in one embodiment of the invention, a thin highly conductive interface film material (not shown) is interposed between the electronic component 204 and the cold plate and/or manifold plate 202. This interface film material may be thermally conductive grease similar to, for example, Chomerics® T710 and Chomerics® T454.

In one embodiment of the invention, the cold plate, which may include a manifold plate used with the cold plate, as shown in one embodiment of the invention in FIG. 4 (element 202), may include one or more microchannels, bumps, dimples, and/or posts, as one of ordinary skill in the relevant art would appreciate based at least on the teachings provided herein.

According to one embodiment of the invention, the electronic component 204 may be a core, where the core may include one or more microprocessors. In one embodiment of the invention, the electronic component 204 may be a silicon die, of any configuration, which is employed to perform operations and as a result or by-product of operating generates heat, and may be thus considered a heat generating component even though the primary purpose of the electronic component is not to generate heat. In embodiments of the invention, the components of the chassis component 201 may serve to cool the electronic components 204, which may be relatively hot during intensive operation. In one embodiment of the invention, the electronic component 204 may be processors in a computer system 200 with power dissipation, which requires a cooling solution. Without proper cooling, the electronic components 204 may break or cease function correctly.

Although only electronic component 204 is shown in FIG. 2, the chassis component 201 may also be used to cool other type of devices or components that generate heat. For example, components of the chassis component 201 may be configured for dissipating heat from a hard disk unit or a power source used in an electronic apparatus. The chassis component 201 may also be used to dissipate heat from an integrated circuit package or the surface of a printed circuit board. Moreover, in one embodiment of the invention, the chassis component 201 and the frame component 212 may have surfaces contacting one another.

As described elsewhere herein, in embodiments of the invention, the heat pipe 214 is of the type to provide ambient flow of thermal energy.

In alternative embodiments of the invention, the computer system 200 may include a plurality of chassis components 201 in the frame; and a plurality of electronic components 204, each on a respective chassis component 201. Furthermore, the computer system 200 may include a plurality of heat pipes 214, each in a respective cold plate's internal volume, according to embodiments of the invention.

According to embodiments of the invention, the computer system 200 with chassis component 201 is provided with an increased cooling capacity by the pumped loop described above. In addition, the computer system is provided with an ambient cooling pathway provided by heat pipe 214. This configuration allows for increases in the thermal design power (TDP) of the computer system, specifically at the electronic component 204. The computer system 200, therefore, may be afforded an decrease in overall power requirements as the pump 208, which requires power, will not have to operate as frequently as pump 108 in computer system 100 because the heat pipe 214 may provide an ambient or passive pathway for thermal energy to flow from the electronic component 204 to the frame component 212.

It is noted that according to embodiments of the invention, the electronic component 204, such as, but not limited to, a microprocessor, a core with one or more microprocessors, a hard drive, a circuit board, or more than one electronic component. It is also noted that according to one embodiment of the invention, the electronic component 204 does not always operate at its TDP. In certain circumstances, for example, when in a power conservation mode, the electronic component 204 may operate at power levels much lower than the TDP, such as, but not limited to, 10-15 Watts (W) or some other fraction of TDP. According to embodiments of the invention, such as, but not limited to low power conditions, the embodiments of the invention may be capable of dissipating the thermal energy generated by the electronic component 204 when operating at the fractional TDP.

The heat pipe 214, being an ambient component, may be a thermal solution capable of dissipating the thermal energy without consuming electrical power, which may degrade battery life. In embodiments of the invention, the cold plate or manifold 202 in the pumped loop may not allow for a large dissipation of heat, unless the pump 208 is operating. The cold plate or manifold 202 may, according to embodiments of the invention, improve the dissipation of thermal energy over cold plate 102 by the inclusion of the heat pipe 214, and may allow the pump 208 to turn on less frequently. This may result in a substantial savings in average power.

For example, and not by way of limitation, if the pump 208 consumed 1 W of power and would need to operate an average of 25% of the time with a conventional cold plate, then the average power consumption of the pump 208 would be 0.25 W, which may be a substantial amount. If the passive (ambient) dissipation of the cold plate or manifold 202 was enhanced such that the pump would only need to operate 5% of the time, then the average power may be reduced to 0.05 W, which may be a substantial improvement.

According to one embodiment of the invention, the imbedding of the heat pipe 214 into the cold plate or manifold 202 may enhance the passive dissipation of the cold plate or manifold 202. In one embodiment of the invention, the heat pipe 214 may be attached to the heat exchanger 210 or other passive heat dissipation device to transfer the thermal energy to the frame component 212. In addition, according to one embodiment of the invention, the parallel heat flow path provided by the heat pipe 214 may enhance the overall thermal solution performance when the pumped loop is activated.

According to the above-described embodiments of the invention, a method for including the heat pipe 214 may provide passive dissipation in the thermal solution and yet allow for the higher TDP capability of a pumped loop. The parallel usage of both heat flow paths may allow for increased battery life and/or reduce power consumption, as well as reduced noise from the pump 208 or any included fans or other cooling equipment of the frame component 212.

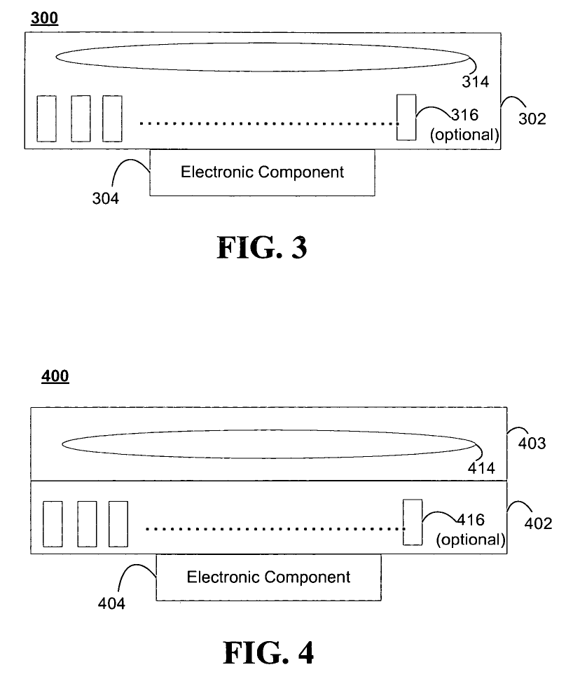

FIG. 3 is a cross-sectional diagram of a cold plate with a heat pipe according to one embodiment of the invention. As described with respect to FIG. 2, the cold plate 102 may be modified to include a heat pipe 214. The result is cold plate 202, shown, according to one embodiment, in cross-section 300, which includes a cold plate 302 and an electronic component 304. In the cross-section 300, the cold plate 302 may include a heat pipe 314, according to one embodiment of the invention. Moreover, the cold plate 302 may also include optional microchannels 316. According to embodiments of the invention, the optional microchannels 316 may be fins, dimples, posts or other features which facilitate cooling, as one of ordinary skill in the art would recognize based at least on the teachings provided herein.

FIG. 4 is a cross-sectional diagram of a manifold plate with a heat pipe according to one embodiment of the invention. As described with respect to FIG. 2, the cold plate 102 may be modified to include a heat pipe 214. The result is cold plate 202, shown, according to one embodiment, in cross-section 400, which includes a portion of cold plate (element 402), and a manifold plate 403, thermally coupled to an electronic component 404. In the cross-section of cold plate 400, the cold plate 402 may be in thermal and/or fluidic contact with the manifold plate 403. The manifold plate may include a heat pipe 314, according to one embodiment of the invention. Moreover, the cold plate 402 may also include optional microchannels 416. According to embodiments of the invention, the optional microchannels 416 may be fins, dimples, posts or other features which facilitate cooling, as one of ordinary skill in the art would recognize based at least on the teachings provided herein.

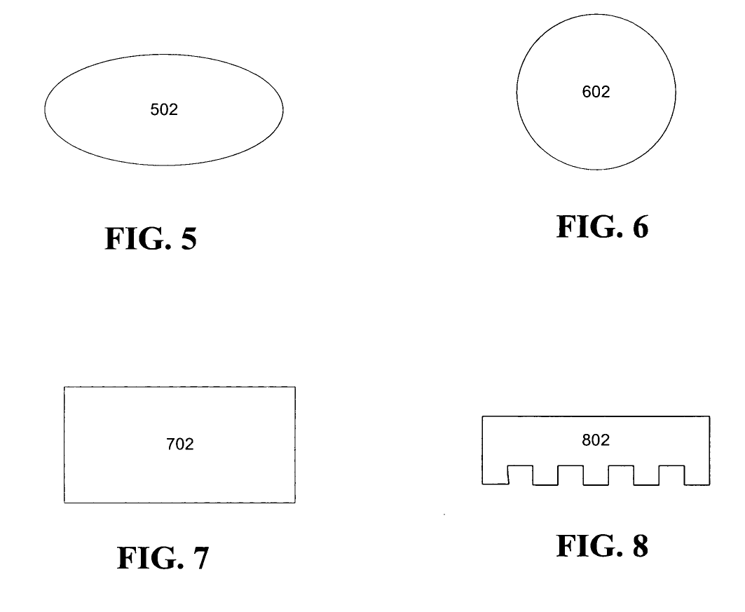

FIGS. 5-8 are cross-sectional diagrams of various examples of heat pipe shapes according to embodiments of the invention. The heat pipes of the embodiments of the invention are not limited to these shapes, as one of ordinary skill would recognize based at least on the teachings provided herein, these and other shapes, such as other polygonal shapes, may be used. Specifically, FIG. 5 shows an example of a cross-section of an elliptical or oval heat pipe 502, according to one embodiment of the invention. FIG. 6 shows an example of a cross-section of a circular heat pipe 602, according to one embodiment of the invention. FIG. 7 shows an example of a cross-section of a rectangular heat pipe 702, according to one embodiment of the invention. FIG. 8 shows an example of a cross-section of an irregular or combinational polygonal shaped heat pipe 802, according to one embodiment of the invention.

As one of ordinary skill in the relevant art would appreciate based at least on the teachings provided herein, the embodiments of the invention allow for changes in the shape of the heat pipe at various places along lengths of the heat pipe. In additional embodiments of the invention, the heat pipe may be bent at the various places along lengths of the heat pipe.

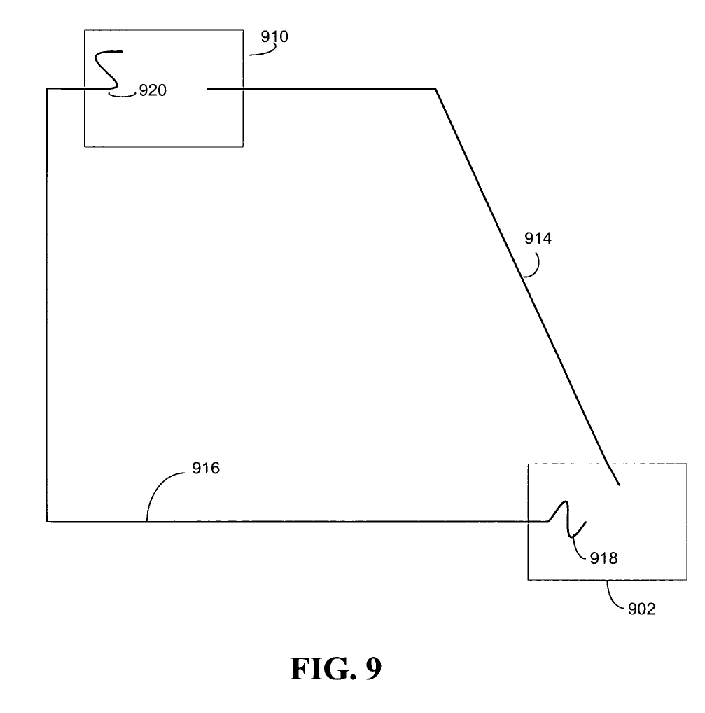

FIG. 9 illustrates examples of heat pipe configurations according to embodiments of the invention. In FIG. 9, elements 914 and 916, both of which are heat pipes, are embodiments of the invention. In one embodiment of the invention, the heat pipe 914 may be imbedded in a direct or straight fashion within a cold plate or manifold 902 and a heat exchanger 910. In another embodiment of the invention, the heat pipe 914 may be imbedded with one or more bends or curves, along any angle within either or both the cold plate or manifold 902 and the heath exchanger 910.

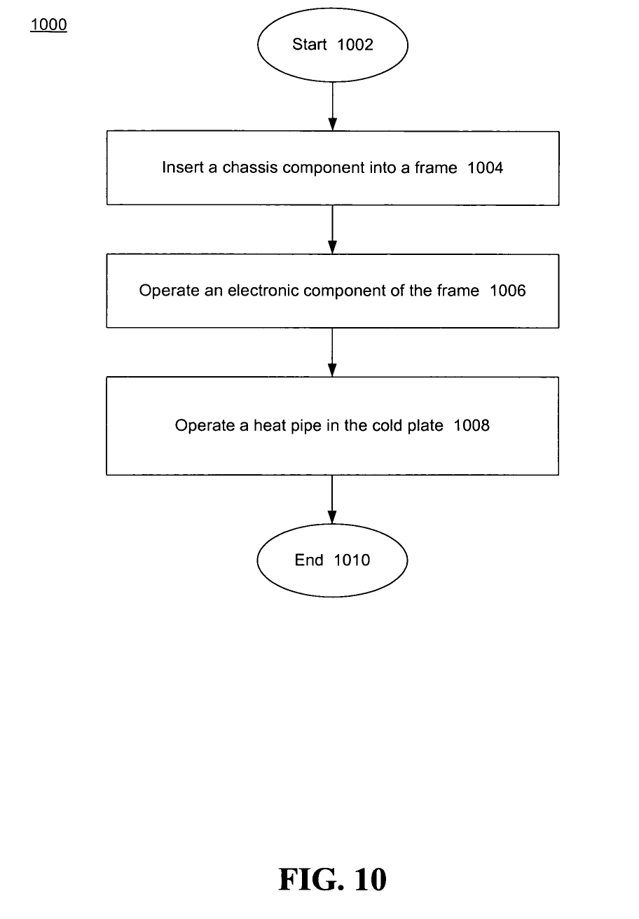

FIG. 10 shows a flow diagram of the transfer of thermal energy by a heat pipe in a computer system according to an embodiment of the invention. According to one embodiment of the invention, the method of operating a computer system may begin at element 1002 and may proceed to inserting a chassis component into a frame (element 1004), where the frame may include a frame component and an electronic component, and where the chassis component may include a heat exchanger on the chassis component. In one embodiment of the invention, a conduit of tubing may provide for fluid flow from the heat exchanger to a cold plate, and a pump may provide for the flow of the fluid between the heat exchanger and the cold plate.

In one embodiment of the invention, the method may operate the electronic component of the frame (element 1006), such that thermal energy may transfer from the electronic component to the cold plate, where the cold plate with a cold plate internal volume to which thermal energy from the electronic component may be transferred. Furthermore, in one embodiment of the present invention, the method may operate a heat pipe in the cold plate internal volume (element 1008); where the heat pipe may be thermally coupled to the heat exchanger to provide for the transfer of heat from the cold plate to the heat exchanger independently of the conduit of tubing, and where the heat exchanger may be thermally coupled to the frame component to provide for the transfer of heat from the heat exchanger to the frame component.

The method may then proceeds to element 1010, where it may be repeated as one of ordinary skill in the relevant art would appreciate based at least on the teachings provided herein. According to one embodiment of the invention, a substantial amount of the thermal energy generated by the electronic component may be transferred to the heat exchanger via the heat pipe.

Embodiments of the present invention may be described in sufficient detail to enable those skilled in the art to practice the invention. Other embodiments may be utilized, and structural, logical, and intellectual changes may be made without departing from the scope of the present invention. Moreover, it is to be understood that various embodiments of the invention, although different, are not necessarily mutually exclusive. For example, a particular feature, structure, or characteristic described in one embodiment may be included within other embodiments. Those skilled in the art can appreciate from the foregoing description that the techniques of the embodiments of the invention can be implemented in a variety of forms. Therefore, while the embodiments of this invention have been described in connection with particular examples thereof, the true scope of the embodiments of the invention should not be so limited since other modifications will become apparent to the skilled practitioner upon a study of the drawings, specification, and following claims.

What is claimed is:

1. A computer system comprising:
a frame including a frame component and an electronic component;
a cold plate in the chassis component, the cold plate with a cold plate internal volume to which thermal energy from the electronic component is transferred;
a chassis component in the frame, wherein the chassis component includes a heat exchanger on the chassis component, a conduit of tubing to provide for fluid flow from the heat exchanger to the cold plate, and a pump to provide for the flow of the fluid between the heat exchanger and the cold plate; and
a heat pipe in the cold plate internal volume; wherein the heat pipe is thermally coupled to the heat exchanger to provide for the transfer of heat from the cold plate to the heat exchanger independently of the conduit of tubing, and wherein the heat exchanger is thermally coupled to the frame component to provide for the transfer of heat from the heat exchanger to the frame component.

2. The computer system of claim 1, wherein a substantial amount of the thermal energy generated by the electronic component transfers to the heat exchanger via the heat pipe.

3. The computer system of claim 1, wherein the cold plate includes a manifold plate, wherein the manifold plate contains the heat pipe.

4. The computer system of claim 1, wherein the cold plate includes one or more microchannels.

5. The computer system of claim 1, wherein the electronic component is a core, the core including one or more microprocessors.

6. The computer system of claim 1, wherein the chassis component and the frame component have surfaces contacting one another.

7. The computer system of claim 1, wherein the heat pipe includes a shaped surface, wherein the shaped surface is at least one of circular, elliptical, or polygonal.

8. The computer system of claim 7, wherein the shaped surface of heat pipe is different for a length of the heat pipe than at least one other length of the heat pipe.

9. The computer system of claim 7, wherein the heat pipe bends in one or more locations.

10. The computer system of claim 1, wherein the heat pipe is of the type to provide ambient flow of thermal energy.

11. The computer system of claim 1, further comprising:
a plurality of chassis components in the frame; and
a plurality of electronic components, each on a respective chassis component.

12. The computer system of claim 11, further comprising:
a plurality of heat pipes, each in a respective internal volume of the cold plate.

13. An apparatus, comprising:
a heat exchanger;
a cold plate with a cold plate internal volume;
a conduit of tubing to provide for fluid flow from the heat exchanger to the cold plate;
a pump to provide for the flow of the fluid between the heat exchanger and the cold plate; and
a heat pipe in the cold plate internal volume; wherein the heat pipe is thermally coupled to the heat exchanger to provide for the transfer of heat from the cold plate to the heat exchanger independently of the conduit of tubing.

14. The apparatus of claim 13, wherein a substantial amount of the thermal energy of the cold plate transfers to the heat exchanger via the heat pipe.

15. The apparatus of claim 13, wherein the cold plate includes a manifold plate, wherein the manifold plate contains the heat pipe.

16. The apparatus of claim 13, wherein the cold plate includes one or more microchannels.

17. The apparatus of claim 13, wherein the heat pipe includes a shaped surface, wherein the shaped surface is at least one of circular, elliptical or polygonal.

18. The apparatus of claim 17, wherein the shaped surface of heat pipe is different for a length of the heat pipe than at least one other length of the heat pipe.

19. The apparatus of claim 17, wherein the heat pipe bends in one or more locations.

20. The apparatus of claim 13, wherein the heat pipe is of the type to provide ambient flow of thermal energy.

21. A method of operating a computer system, comprising:
inserting a chassis component into a frame, wherein the frame includes a frame component and an electronic component, and wherein the chassis component includes a heat exchanger on the chassis component, a conduit of tubing to provide for fluid flow from the heat exchanger to a cold plate, and a pump to provide for the flow of the fluid between the heat exchanger and the cold plate;
operating the electronic component of the frame, such that thermal energy transfers from the electronic component to the cold plate, wherein the cold plate with a cold plate internal volume to which thermal energy from the electronic component is transferred; and
operating a heat pipe in the cold plate internal volume; wherein the heat pipe is thermally coupled to the heat exchanger to provide for the transfer of heat from the cold plate to the heat exchanger independently of the conduit of tubing, and wherein the heat exchanger is thermally coupled to the frame component to provide for the transfer of heat from the heat exchanger to the frame component.

22. The method of claim 21, wherein a substantial amount of the thermal energy generated by the electronic component transfers to the heat exchanger via the heat pipe.

23. The method of claim 21, wherein the heat pipe is of the type to provide ambient flow of thermal energy.
